(19) United States
(12) Patent Application Publication
(10) Pub. No.: US 2011/0195562 A1
(43) Pub. Date: Aug. 11, 2011

(54) Sputtering Apparatus, Thin-Film Forming Method, and Manufacturing Method for a Field Effect Transistor

(75) Inventors: Takaomi Kurata, Chiba (JP); Junya Kiyota, Chiba (JP); Makoto Arai, Chiba (JP); Yasuhiko Akamatsu, Chiba (JP); Satoru Ishibashi, Chiba (JP); Kazuya Saito, Chiba (JP)

(73) Assignee: ULVAC, INC., Chigasaki-shi, Kanagawa (JP)

(21) Appl. No.: 13/123,727

(22) PCT Filed: Oct. 14, 2009
(86) PCT No.: PCT/JP2009/005342

§ 371 Date: Apr. 12, 2011

(30) Foreign Application Priority Data
Oct. 16, 2008 (JP) 2008-267918

(51) Int. Cl. H01L 21/203; C23C 14/34

(52) U.S. Cl. 438/481; 204/298.12; 257/E21.099

(57) ABSTRACT

[Object] To provide a sputtering apparatus, a thin-film forming method, and a manufacturing method for a field effect transistor, which are capable of reducing damage of a base layer.

[Solving Means] A sputtering apparatus according to an embodiment of the present invention is a sputtering apparatus for forming a thin-film on a surface to be processed of a substrate 10, and includes a vacuum chamber 61, a supporting portion 93, a target 80, and a magnet 83. The magnet 83 generates plasma forming a region to be sputtered 80a, and moves the region to be sputtered 80abetween a first position in which the region to be sputtered 80a is not opposed to the surface to be processed and a second position in which the region to be sputtered is opposed to the surface to be processed. With this, it is possible to weaken incident energy of sputtered particles incident on the surface to be processed of the substrate 10 from the region to be sputtered 80a, and to protect the base layer.

### TECHNICAL FIELD

The present invention relates to a sputtering apparatus for forming a thin-film on a substrate, a thin-film forming method using the same, and a manufacturing method for a field effect transistor.

### BACKGROUND ART

Conventionally, in a step of forming a thin-film on a substrate, there has been used a sputtering apparatus. The sputtering apparatus includes a sputtering target (hereinafter, abbreviated as “target”) arranged in the inside of the vacuum chamber and a plasma generation means for generating plasma in vicinity of the surface of the target. The sputtering apparatus subjects the surface of the target to sputtering using ions in the plasma so that particles (sputtered particles) sputtered from the target are deposited on the substrate. In this manner, a thin-film is formed (for example, see Patent Document 1).

Cited Document

Patent Document

Patent Document 1: Japanese Patent Application Laid-open No. 2007-39712

### SUMMARY

Problem to be solved by the Invention

A thin-film (hereinafter, also referred to as “sputtered thin-film”), which is formed by the sputtering method, has higher adhesion with respect to the substrate in comparison with a thin-film formed by a vacuum deposition method or the like because the sputtered particles incoming from the target are made incident on the surface of the substrate with high energy. Thus, a base layer (base film or base substrate) on which the sputtered thin-film is formed is easy to be greatly damaged due to collision of the incident sputtered particles. For example, when an active layer of a thin-film transistor is formed by the sputtering method, desired film properties may not be obtained due to the damage of the base layer.

In the above-mentioned circumstances, it is an object of the present invention to provide a sputtering apparatus, a thin-film forming method, and a manufacturing method for a field effect transistor, which are capable of reducing damage of a base layer.

Means for solving the Problem

A sputtering apparatus according to an embodiment of the present invention is a sputtering apparatus for forming a thin-film on a surface to be processed of a substrate, and includes a vacuum chamber, a supporting portion, a target, and a plasma generation means.

The vacuum chamber keeps a vacuum state.

The supporting portion is arranged in an inside of the vacuum chamber, and supports the substrate.

The target is arranged in parallel to the surface to be processed of the substrate supported by the supporting portion, and has a surface to be sputtered.

The plasma generation means generates plasma forming a region to be sputtered from which sputtered particles are emitted by sputtering the surface to be sputtered, and moves the region to be sputtered between a first position in which the region to be sputtered is not opposed to the surface to be processed and a second position in which the region to be sputtered is opposed to the surface to be processed.

A thin-film forming method according to an embodiment of the present invention includes arranging a substrate, which has a surface to be processed, in a vacuum chamber.

Plasma for sputtering a target is generated.

A region to be sputtered of the target is moved between a first position in which the region to be sputtered of the target is not opposed to the surface to be processed and a second position in which the region to be sputtered of the target is opposed to the surface to be processed.

A manufacturing method for a field effect transistor according to an embodiment of the present invention includes forming a gate insulating film on a substrate.

The substrate is arranged in an inside of a vacuum chamber in which a target having In-Ga-Zn-O-based composition is arranged.

Plasma for sputtering the target is generated.

A region to be sputtered of the target is moved between a first position in which the region to be sputtered of the target is not opposed to the surface to be processed and a second position in which the region to be sputtered of the target is opposed to the surface to be processed, to thereby form an active layer on the gate insulating film.

### BRIEF DESCRIPTION OF DRAWINGS

FIG. 1 A plan view showing a vacuum processing apparatus according to a first embodiment.

FIG. 2 A plan view showing a holding mechanism.

FIG. 3 A plan view showing a first sputtering chamber.

FIGS. 4 Schematic diagrams each showing a sputtering state.

FIG. 5 A flow chart showing a substrate-processing process.

FIG. 6 A view showing a sputtering apparatus used in an experiment.

FIG. 7 A view showing a film thickness distribution of a thin-film obtained by the experiment.

FIG. 8 A view describing an incident angle of sputtered particles.

FIG. 9 A view showing a film-forming rate of the thin-film obtained by the experiment.

FIG. 10 A view showing ON-state current characteristics and OFF-state current characteristics when each of samples of thin-film transistors manufactured by the experiment is annealed at 200° C.

FIG. 11 A view showing ON-state current characteristics and OFF-state current characteristics when each of samples of thin-film transistors manufactured by the experiment is annealed at 400° C.

FIGS. 12 A plan view showing a first sputtering chamber according to a second embodiment.

### DETAILED DESCRIPTION

A sputtering apparatus according to an embodiment of the present invention is a sputtering apparatus for forming a thin-film on a surface to be processed of a substrate, and includes a vacuum chamber, a supporting portion, a target, and a plasma generation means.

The vacuum chamber keeps a vacuum state.

The supporting portion is arranged in an inside of the vacuum chamber, and supports the substrate.

The target is arranged in parallel to the surface to be processed of the substrate supported by the supporting portion, and has a surface to be sputtered.

The plasma generation means generates plasma forming a region to be sputtered from which sputtered particles are emitted by sputtering the surface to be sputtered, and moves the region to be sputtered between a first position in which the region to be sputtered is not opposed to the surface to be processed and a second position in which the region to be sputtered is opposed to the surface to be processed.

The above-mentioned sputtering apparatus moves the region to be sputtered, to thereby change the incident angle of the sputtered particles with respect to the surface to be processed of the substrate. The sputtered particles incident in a direction oblique to the surface to be processed from the first position has smaller incident energy (the number of incident particles per unit area) in comparison with the sputtered particles incident in a perpendicular direction, and hence the damage received by the base layer is smaller. Then, by making the sputtered particles incident in the perpendicular direction from the second position, it is possible to achieve film formation having higher film-forming speed, while the base layer receives smaller damage.

The plasma generation means may include a magnet for forming a magnetic field on a side of the surface to be sputtered of the target, and the magnet may be arranged to be movable relative to the supporting portion.

The above-mentioned plasma generation means controls plasma density due to the magnetic field applied by the magnet (magnetron sputtering). In the magnetron sputtering, a region to be sputtered is eccentrically located on the surface of the target. By moving the magnet, to thereby move the region to be sputtered, it is possible to control the incident direction of the sputtered particles with respect to the surface to be processed.

The surface to be sputtered may include a first region in which the surface to be sputtered is not opposed to the surface to be processed, and a second region in which the surface to be sputtered is opposed to the surface to be processed, and the magnet may be arranged to be movable between the first region and the second region.

When the first region on the surface to be sputtered, that is, the region positioned in the oblique direction with respect to the surface to be processed is set as the region to be sputtered, the incident direction of the sputtered particles with respect to the surface to be processed can be set as the oblique direction. Further, when the second region, that is, the region positioned in the perpendicular direction with respect to the surface to be processed is set as the region to be sputtered, the incident direction can be set as the perpendicular direction.

The target may move together with the magnet.

By moving the target together with the magnet, it is possible to control the direction of the region to be sputtered as seen from the surface to be processed.

A thin-film forming method according to an embodiment of the present invention includes arranging a substrate, which has a surface to be processed, in a vacuum chamber.

Plasma for sputtering a target is generated.

A region to be sputtered of the target is moved between a first position in which the region to be sputtered of the target is not opposed to the surface to be processed and a second position in which the region to be sputtered of the target is opposed to the surface to be processed.

A manufacturing method for a field effect transistor according to an embodiment of the present invention includes forming a gate insulating film on a substrate.

The substrate is arranged in an inside of a vacuum chamber in which a target having In-Ga-Zn-O-based composition is arranged;

Plasma for sputtering the target is generated.

A region to be sputtered of the target is moved between a first position in which the region to be sputtered of the target is not opposed to the surface to be processed and a second position in which the region to be sputtered of the target is opposed to the surface to be processed, to thereby form an active layer on the gate insulating film.

According to this manufacturing method for a field effect transistor, it is possible to protect the gate insulating film easy to be damaged due to the incident energy during formation of the active layer by the sputtering.

Hereinafter, embodiments of the present invention will be described with reference to the drawings.

First embodiment

A vacuum processing apparatus 100 according to a first embodiment will be described.

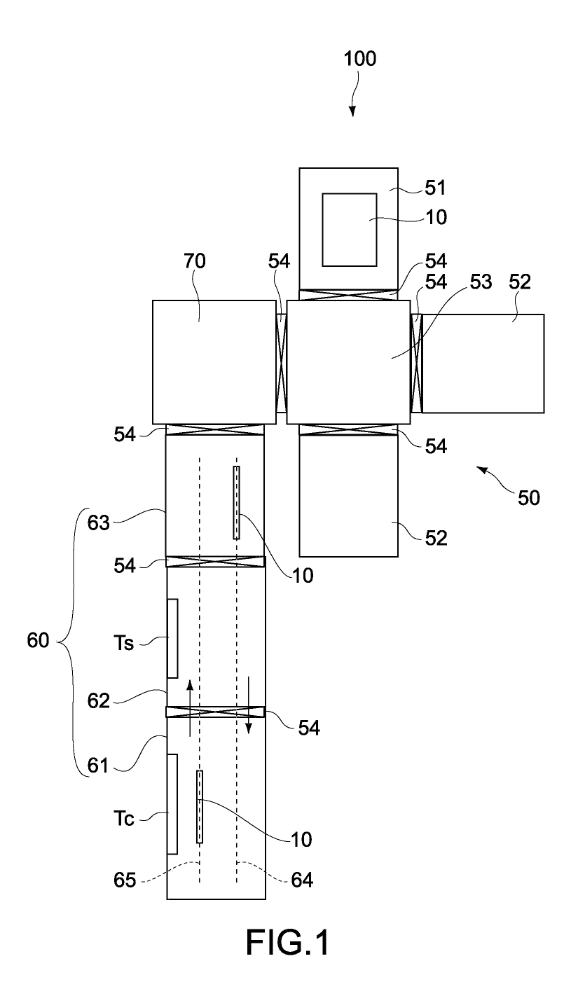

FIG. 1 is a schematic plan view showing the vacuum processing apparatus 100.

The vacuum processing apparatus 100 is an apparatus for processing a glass substrate (hereinafter, abbreviated as substrate) 10 to be used as a base material in a display, for example. Typically, the vacuum processing apparatus 100 is an apparatus responsible for a part of the manufacture of a field effect transistor having a so-called bottom gate type transistor structure.

The vacuum processing apparatus 100 includes a cluster type processing unit 50, an in-line type processing unit 60, and a posture changing chamber 70. Those chambers are formed in the inside of a single vacuum chamber or in the insides of combined vacuum chambers.

The cluster type processing unit 50 includes a plurality of horizontal type processing chambers. The plurality of horizontal type processing chambers process the substrate 10 in the state in which the substrate 10 is arranged substantially horizontally. Typically, the cluster type processing unit 50 includes a load lock chamber 51, a conveying chamber 53, and a plurality of CVD (Chemical Vapor Deposition) chambers 52.

The load lock chamber 51 switches between an atmospheric pressure state and a vacuum state, loads from the outside of the vacuum processing apparatus 100 the substrate 10, and unloads to the outside the substrate 10. The conveying chamber 53 includes a conveying robot (not shown). Each of the CVD chambers 52 is connected to the conveying chamber 53, and performs a CVD process with respect to the substrate 10. The conveying robot of the conveying chamber 53 carries the substrate 10 into the load lock chamber 51, each of the CVD chambers 52, and the posture changing chamber 70 to be described later. Further, the conveying robot of the conveying chamber 53 carries the substrate 10 out of each of the above-mentioned chambers.

In the CVD chambers 52, typically, a gate insulating film of the field effect transistor is formed.

It is possible to keep the conveying chamber 53 and the CVD chambers 52 under a predetermined degree of vacuum.

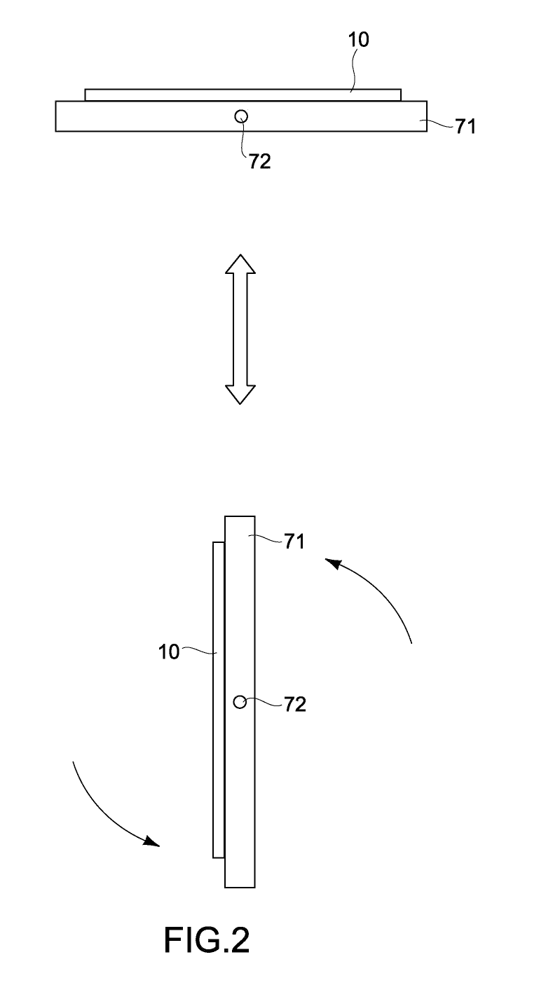

The posture changing chamber 70 changes the posture of the substrate 10 from the horizontal state to the vertical state and in turn, from the vertical state to the horizontal state. For example, as shown in FIG. 2, within the posture changing chamber 70, there is provided a holding mechanism 71 for holding the substrate 10. The holding mechanism 71 is configured to be rotatable about a rotating shaft 72. The holding mechanism 71 holds the substrate 10 by use of a mechanical chuck, a vacuum chuck, or the like. The posture changing chamber 70 can be kept under substantially the same degree of vacuum as the conveying chamber 53.

By driving a driving mechanism (not shown) connected to the both ends of the holding mechanism 71, the holding mechanism 71 may be rotated.

The cluster type processing unit 50 may be provided with a heating chamber and other chambers for performing other processes in addition to the CVD chambers 52 and the posture changing chamber 70, which are connected to the conveying chamber 53.

The in-line type processing unit 60 includes a first sputtering chamber 61 (vacuum chamber), a second sputtering chamber 62, and a buffer chamber 63, and processes the substrate 10 in the state in which the substrate 10 is oriented substantially upright.

In the first sputtering chamber 61, typically, as will be described later, a thin-film having In-Ga-Zn-O-based composition (hereinafter, abbreviated as IGZO film) is formed on the substrate 10. In the second sputtering chamber 62, a stopper layer film is formed on that IGZO film. The IGZO film constitutes an active layer for the field effect transistor. The stopper layer film functions as an etching protection layer for protecting a channel region of the IGZO film from etchant in a step of patterning a metal film constituting a source electrode and a drain electrode and in a step of etching and removing an unnecessary region of the IGZO film.

The first sputtering chamber 61 includes a sputtering cathode Tc including a target material for forming the IGZO film. The second sputtering chamber 62 includes a single sputtering cathode Ts including a target material for forming the stopper layer film.

The first sputtering chamber 61 is, as will be described later, configured as a sputtering apparatus using a fixed-type film-forming method. On the other hand, the second sputtering chamber 62 may be configured as a sputtering apparatus using the fixed-type film-forming method or as a sputtering apparatus using a passing-type film-forming method.

Within the first sputtering chamber 61, second sputtering chamber 62, and the buffer chamber 63, there are prepared two conveying paths for the substrate 10, which are constituted of a forward path 64 and a return path 65, for example. Further, a supporting mechanism (not shown) is provided for supporting the substrate 10 in the state in which the substrate 10 is oriented upright or in the state in which the substrate 10 is slightly inclined from the upright state. The substrate 10 supported by the supporting mechanism is adapted to be conveyed through conveying rollers and a mechanism such as a rack-and-pinion mechanism, which are not shown.

Between the chambers, gate valves 54 are respectively provided. The gate valves 54 are controlled independently of each other to be opened and closed.

The buffer chamber 63 is connected between the posture changing chamber 70 and the second sputtering chamber 62. The buffer chamber 63 functions as a buffering region for pressurized atmosphere of the posture changing chamber 70 and pressurized atmosphere of the second sputtering chamber 62. For example, when the gate valve 54 between the posture changing chamber 70 and the buffer chamber 63 is opened, the degree of vacuum of the buffer chamber 63 is controlled to be substantially equal to the pressure within the posture changing chamber 70. Alternatively, when the gate valve 54 between the buffer chamber 63 and the second sputtering chamber 62 is opened, the degree of vacuum of the buffer chamber 63 is controlled to be substantially equal to the pressure within the second sputtering chamber 62.

In the CVD chambers 52, in some cases, specialty gas such as cleaning gas is used for cleaning those chambers. For example, in a case where the CVD chambers 52 are configured as vertical type apparatuses, there is a fear that the supporting mechanism, the conveying mechanism, and the like, as provided in the second sputtering chamber 62, which are peculiar to the vertical type processing apparatus, may be corroded due to the specialty gas, or the like. However, in the embodiment, the CVD chambers 52 are configured as the horizontal apparatuses, and hence the above-mentioned problem can be solved.

For example, in a case where the sputtering apparatus is configured as a horizontal apparatus, for example, when the target is arranged directly above the substrate, there is a fear that the target material adhering to the periphery of the target may drop on the substrate with a result that the substrate 10 may be contaminated. On the contrary, when the target is arranged under the base material, there is a fear that the target material adhering to a deposition preventing plate arranged in the periphery of the substrate may drop on an electrode with a result that the electrode may be contaminated. There is a fear that, due to the above-mentioned contaminations, an abnormal electrical discharge may occur during the sputtering process. However, the sputtering chamber 62 is configured as a vertical type processing chamber, and hence the above-mentioned problem can be solved.

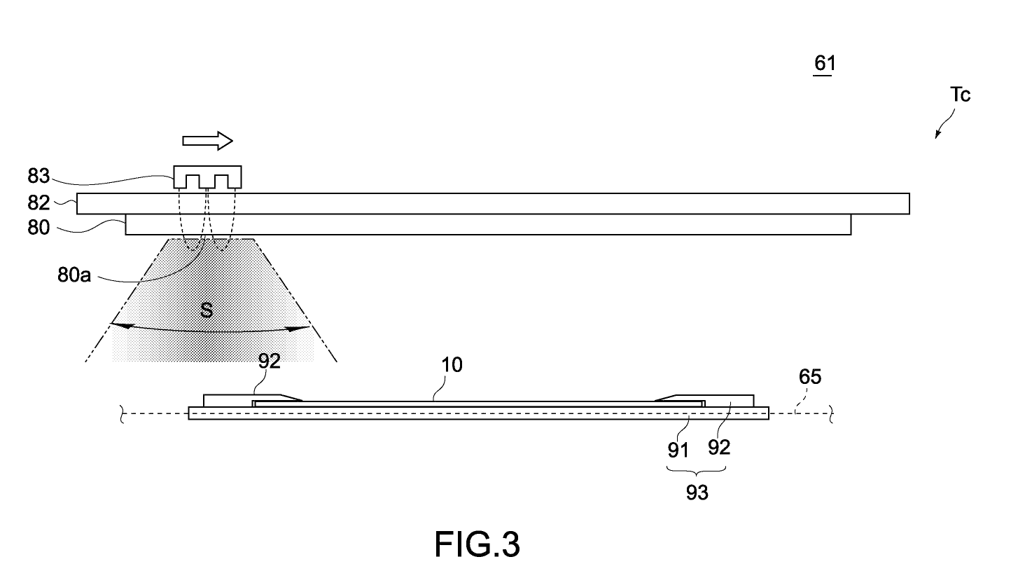

Next, the first sputtering chamber 61 will be described in detail. FIG. 3 is a schematic plan view showing the first sputtering chamber 61.

The first sputtering chamber 61 includes the sputtering cathode Tc as described above. The sputtering cathode Tc includes a target 80, a backing plate 82, and a magnet 83. The first sputtering chamber 61 is connected to a gas introduction line (not shown). Through the gas introduction line, to the first sputtering chamber 61, gas for sputtering such as argon and reactive gas such as oxygen are introduced.

The target 80 is constituted of an ingot of film- forming material or a sintered body. In this embodiment, the target 80 is constituted of an alloy ingot or a sintered body material having In-Ga-Zn-O composition. The target 80 is attached to the substrate 10 in such a manner that a surface to be sputtered of target 80 is in parallel to a surface to be processed of the substrate 10. The target 80 has an area larger than that of the substrate 10. The surface to be sputtered of the target 80 includes a region (second region) in which the surface to be sputtered of the target 80 is not opposed to the substrate 10 and a region (first region) in which the surface to be sputtered of the target 80 is opposed to the substrate 10. Of the surface to be sputtered of the target 80, a region (to be described later) in which the sputtering is to proceed is referred to as a region to be sputtered 80a.

The backing plate 82 is configured as an electrode to be connected to an alternating-current power source (including high-frequency power source) or a direct-current power source, which are not shown. The backing plate 82 may include a cooling mechanism in which cooling medium such as cooling water is circulated. The backing plate 82 is attached on the back surface (the surface in an opposite side of the surface to be sputtered) of the target 80.

The magnet 83 is constituted of a combined body of a permanent magnet and a yoke. The magnet 8 forms a predetermined magnetic field 84 in the vicinity of a surface (surface to be sputtered) of the target 80. The magnet 83 is attached to the back side (a side opposite to the target 80) of the backing plate 82, and is formed so as to be movable in one direction parallel to the surface to be sputtered of the target 80 (at the same time, parallel to the surface to be processed of the substrate 10) through the driving mechanism (not shown).

The sputtering cathode Tc configured in the above-mentioned manner generates plasma within the first sputtering chamber 61 by use of a plasma generation means including the power sources, the backing plate 82, the magnet 83, the gas introduction line, and the like. That is, when predetermined alternating-current power or predetermined direct-current power is applied on the backing plate 82, plasma of gas for sputtering is generated in the vicinity of the surface to be sputtered of the target 80. Then, by ions in the plasma, the surface to be sputtered of the target 80 is sputtered (the region to be sputtered 80a is formed). Further, a high density plasma (magnetron discharge) is generated due to the magnetic field formed on the target surface by the magnet 83, and hence it is possible to obtain density distribution of plasma, which corresponds to magnetic field distribution. When the plasma density is controlled, the entire region of the surface to be sputtered is not evenly sputtered and a region to become the region to be sputtered 80a is limited. The region to be sputtered 80a depends on the location of the magnet 83, and moves along with the movement of the magnet 83.

As shown in FIG. 3, sputtered particles generated from the region to be sputtered 80a are emitted from the region to be sputtered 80a within an angle range S. The angle range S is controlled depending on formation conditions of plasma or the like. The sputtered particles include particles sputtered from the region to be sputtered 80a in a direction perpendicular to the region to be sputtered 80a, and particles sputtered from the surface of the target 80 in a direction oblique to the surface of the target 80. The sputtered particles sputtered from the target 80 are deposited on the surface to be processed of the substrate 10 so that the thin-film is formed.

In the first sputtering chamber 61, the substrate 10 is arranged. The substrate 10 is supported by a supporting portion 93 provided with a supporting plate 91 and clamp mechanisms 92. The substrate 10 is stabilized (fixed) at a predetermined position on the return path 65 during the film formation. The clamp mechanisms 92 hold the peripheral portion of the substrate 10 supported by the supporting region of the supporting plate 91 opposed to the sputtering cathode Tc.

An arrangement relation between the magnet 83 and the substrate 10 will be described.

At a start time of the sputtering, the magnet 83 is arranged in a first position. The first position is a position in which the magnet 83 is not opposed to the substrate 10 via the target 80. That is, the first position corresponds to the back surface in a region in which the magnet 83 is not opposed to the substrate 10, of the surface to be sputtered of the target 80. Although will be described later, when the sputtering proceeds, the magnet 83 is driven through the driving mechanism, and is moved to a second position being a position in which the magnet 83 is opposed to the substrate 10.

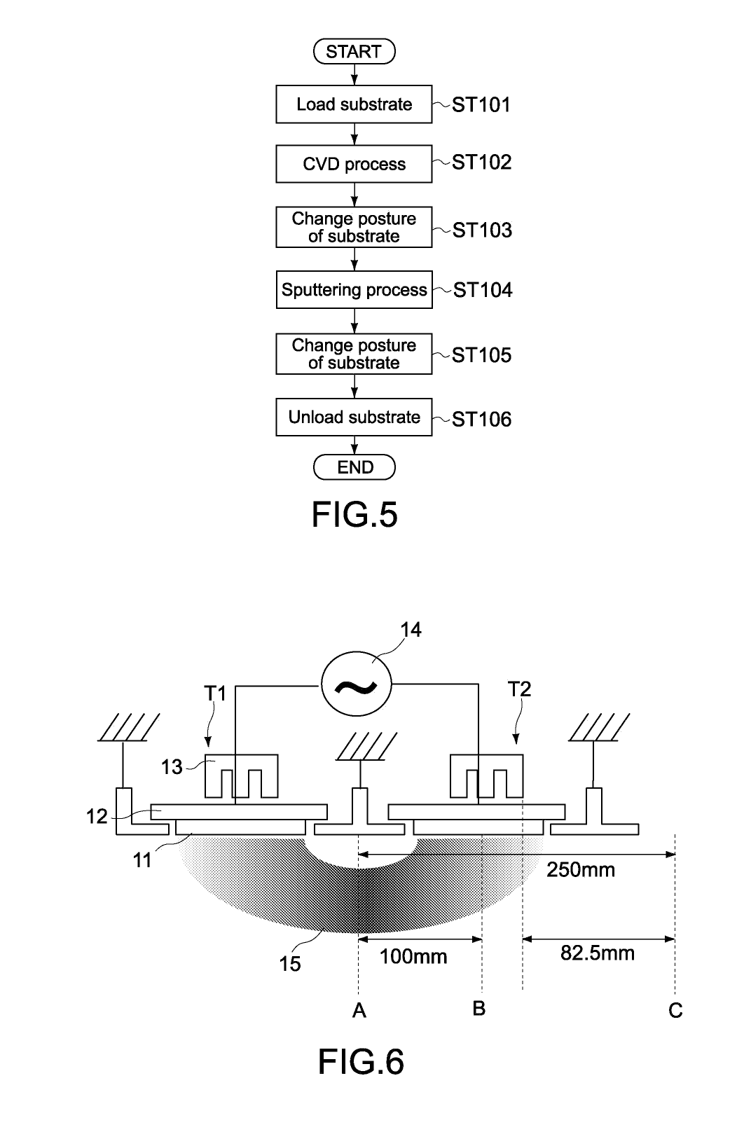

A processing order for the substrate 10 in the vacuum processing apparatus 100 configured in the above-mentioned manner will be described. FIG. 5 is a flow chart showing that order.

The conveying chamber 53, the CVD chambers 52, the posture changing chamber 70, the buffer chamber 63, the first sputtering chamber 61, and the second sputtering chamber 62 are each kept in a predetermined vacuum state. First, the substrate 10 is loaded in the load lock chamber 51 (Step 101). After that, the substrate 10 is conveyed through the conveying chamber 53 into the CVD chambers 52, and a predetermined film, for example, a gate insulating film is formed on the substrate 10 by the CVD process (Step 102). After the CVD process, the substrate 10 is conveyed through the conveying chamber 53 into the posture changing chamber 70, and the posture of the substrate 10 is changed from the horizontal posture to the vertical posture (Step 103).

The substrate 10 in the vertical posture is conveyed through the buffer chamber 63 into the sputtering chamber, and is further conveyed through the forward path 64 up to the end of the first sputtering chamber 61. After that, the substrate 10 takes the return path 65, is stopped within the first sputtering chamber 61, and is subjected to the sputtering process in the following manner. Thus, for example, an IGZO film is formed on the surface of the substrate 10 (Step 104).

With reference to FIG. 3, the substrate 10 is conveyed by the supporting mechanism within the first sputtering chamber 61, and is stopped at a position at which the substrate 10 is opposed to the sputtering cathode Tc. In the first sputtering chamber 61, sputtering gas (argon gas and oxygen gas) at a predetermined flow rate is introduced. As described above, when the electrical field and the magnetic field are applied to the sputtering gas, the sputtering is started.

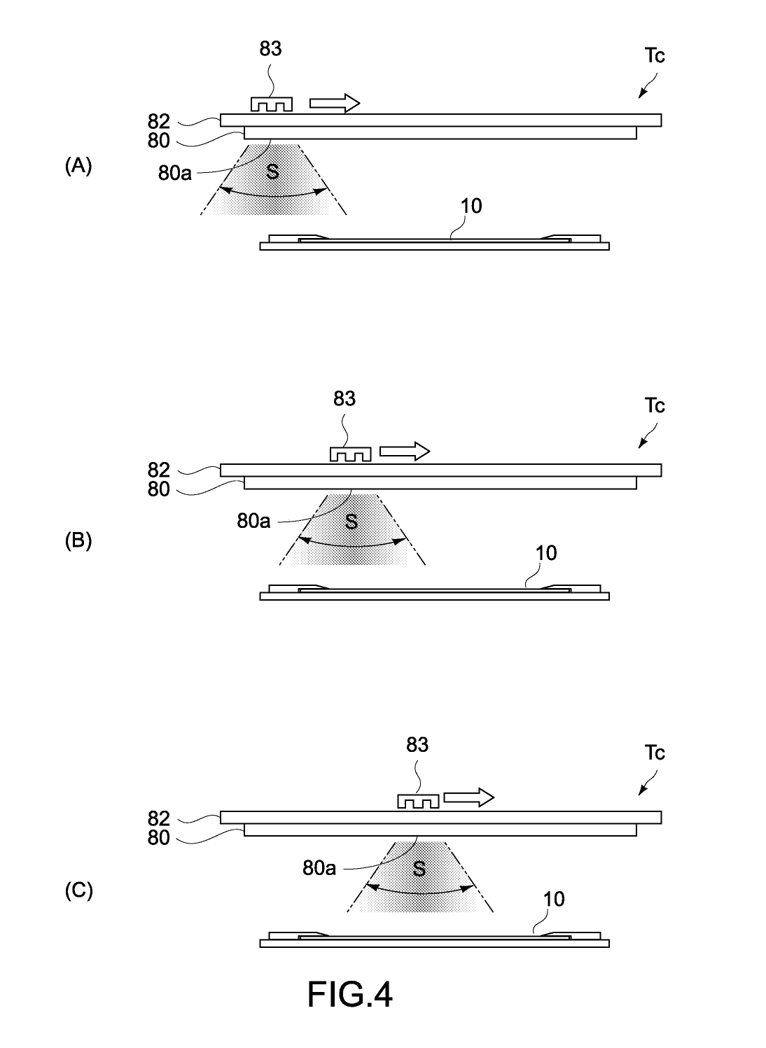

FIGS. 4 are views each showing a sputtering state.

The sputtering proceeds in the order of FIGS. 4(A), 4(B), and 4(C). During the starting phase of the sputtering shown in FIG. 4(A), the magnet 83 is arranged in the first position in which the magnet 83 is not opposed to the substrate 10. The region to be sputtered 80a is generated in the vicinity of the magnet 83, of the surface to be sputtered of the target 80. The sputtered particles emitted from the region to be sputtered 80a are dispersed with a certain angle, arrive at the surface to be processed of the substrate 10, and are deposited. The sputtered particles arriving at the surface to be processed in this phase are the sputtered particles emitted from the region to be sputtered 80a in a direction oblique to the surface to be sputtered. The region to be sputtered 80a is not opposed to the substrate 10, and hence the sputtered particles emitted in a direction perpendicular to the surface to be sputtered cannot arrive at the surface to be processed.

When the film formation is performed using the sputtered particles obliquely incident on a partial region, which is close to the region to be sputtered 80a, of the surface to be processed of the substrate 10, the magnet 83 is driven through the driving mechanism, and is moved as shown in FIG. 4(B). Due to this movement, the magnet 83 is moved from the first position in which the magnet 83 is not opposed to the substrate 10 to the second position in which the magnet 83 is opposed to the substrate 10. It should be noted that also during this movement, the sputtering proceeds (the electrical field and the magnetic field are being applied). The region to be sputtered 80a moves on the surface to be sputtered together with the magnet 83, and takes a position in which the region to be sputtered 80a is opposed to the substrate 10. With this, of the sputtered particles emitted from the region to be sputtered 80a, the sputtered particles emitted in the oblique direction and the perpendicular direction with respect to the surface to be sputtered arrive at the surface to be processed of the substrate 10. A part of the sputtered particles emitted in the oblique direction arrives at a (new) region in which no film is formed on the surface to be processed. On the other hand, the sputtered particles emitted in the perpendicular direction arrive at the region in which the film is already formed during the previous phase shown in FIG. 4(A).

When a film having a predetermined film thickness is formed of the sputtered particles emitted in the perpendicular direction, the magnet 83 is further moved as shown in FIG. 4(B), and the region in which the film is formed of the sputtered particles emitted in the oblique direction during the phase shown in FIG. 4(B) is subjected to further film formation using the sputtered particles emitted in the perpendicular direction. After that, the magnet 83 moves similarly, and the film formation proceeds over the entire region of the surface to be processed of the substrate 10. Although the consecutive movement of the magnet 83 has been described, stepwise movement (repeating proceeding and stop) may be employed.

In the above-mentioned manner, the surface to be processed of the substrate 10 is first subjected to the film formation using the sputtered particles emitted in the oblique direction from the region to be sputtered 80a, and then is subjected to the film formation using the sputtered particles emitted in the perpendicular direction. The number of the sputtered particles emitted in the oblique direction, which arrive at the surface to be processed per unit area, is smaller in comparison with the number of the sputtered particles emitted in the perpendicular direction. Therefore, incident energy received by the surface to be processed per unit area is lower, and the damage received by the surface to be processed is also smaller. On the other hand, the number of the sputtered particles emitted in the oblique direction is small. Therefore, although the film-forming speed is low, due to the sputtered particles emitted in the perpendicular direction following them, it is possible to form a film without greatly reducing the entire film-forming speed. The sputtered particles emitted in the perpendicular direction arrive only at the region in which the film is already formed on the surface to be processed. Therefore, the already formed film serves as a buffering material, and hence the surface to be processed does not receive the damage.

In the sputtering process according to this embodiment, the magnet 83 is moved, and hence in any region of the surface to be processed of the substrate 10, the film formation can proceed by the above-mentioned process. Further, the damage received by the surface to be processed can be reduced, and the film-forming speed can be kept high.

The substrate 10 on which the IGZO film is formed within the first sputtering chamber 61 is conveyed to the second sputtering chamber 62 together with the supporting plate 91. In the second sputtering chamber 62, a stopper layer made of a silicon oxide film, for example, is formed on the surface of the substrate 10 (Step 104).

For the film-forming process in the second sputtering chamber 62, similarly to the film-forming process in the first sputtering chamber 61, the fixed-type film-forming method of forming a film with the substrate 10 being stabilized within the second sputtering chamber 62 is employed. The present invention is not limited thereto, the passing-type film-forming method of forming a film with the substrate 10 being passed through the second sputtering chamber 62 may be employed.

After the sputtering process, the substrate 10 is conveyed through the buffer chamber 63 into the posture changing chamber 70, and the posture of the substrate 10 is changed from the vertical posture to the horizontal posture (Step 105). After that, the substrate 10 is unloaded through the conveying chamber 53 and the load lock chamber 51 to the outside of the vacuum processing apparatus 100 (Step 106).

As described above, according to this embodiment, in the inside of one vacuum processing apparatus 100, it is possible to consistently perform CVD deposition and sputtering deposition without exposing the substrate 10 to the atmosphere. Thus, it is possible to achieve an increase of the productivity. Further, it is possible to prevent moisture and dust existing within the atmosphere from adhering to the substrate 10. Therefore, it is also possible to achieve an increase of the film quality.

Further, as described above, by forming the initial IGZO film under a state in which the incident energy is low, it is possible to reduce the damage of the gate insulating film being the base layer thereof, and hence it is possible to manufacture a field-effect thin-film transistor having high properties.

Second embodiment

A vacuum processing apparatus according to a second embodiment will be described.

In the following, the description of parts having the same configuration as the configuration of the above-mentioned embodiment will be simplified.

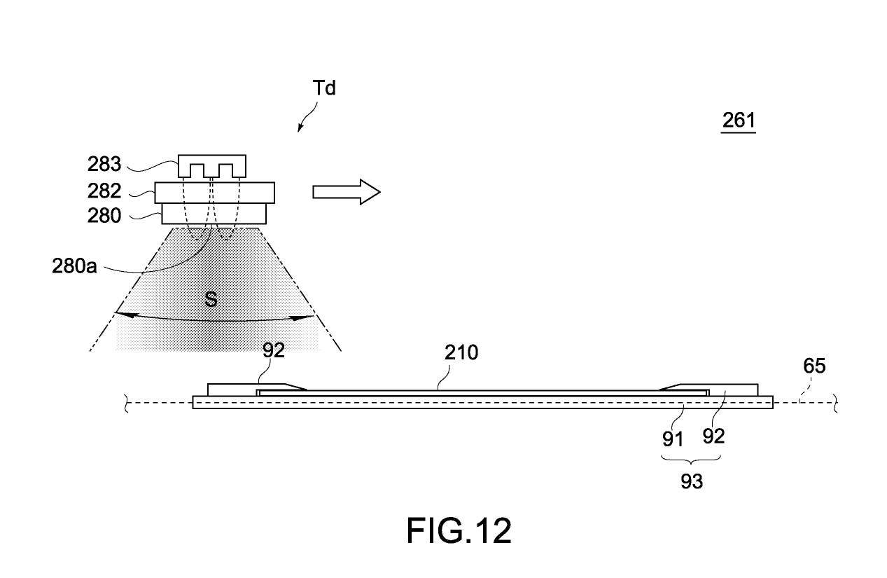

FIG. 12 is a schematic plan view showing a first sputtering chamber 261 according to the second embodiment.

Unlike the vacuum processing apparatus 100 according to the first embodiment, the vacuum processing apparatus according to this embodiment includes a target plate 281 to move together with a magnet 283.

The first sputtering chamber 261 of the vacuum processing apparatus includes a sputtering cathode Td. The sputtering cathode Td is configured to be movable with respect to a substrate 210 being a film-forming target. In particular, the sputtering cathode Td is configured so that the target plate 281 is allowed to take a position in which the target plate 281 is not opposed to the substrate 210.

The sputtering cathode Td includes the target plate 281, a backing plate 282, and the magnet 283.

The sputtering cathode Td according to this embodiment is configured to be movable with respect to the substrate 210 being the film-forming target.

The target plate 281 is attached to be in parallel to the surface to be processed of the substrate 210. The target plate 281 takes the position in which the target plate 281 is opposed to the substrate 210 or takes the position in which the target plate 281 is not opposed the substrate 210 along with movement of the sputtering cathode Td. Therefore, the size of the target plate 281 is smaller than the size of the substrate 210. Of the surface to be sputtered of the target plate 281, a region (to be described later) in which the sputtering is to proceed is referred to as a region to be sputtered 280a.

The backing plate 282 is attached to the back surface (a surface in an opposite side to the surface to be sputtered) of the target plate 281.

The magnet 283 is arranged on the back side (a side opposite to the target 280) of the backing plate 282. Unlike the magnet 83 according to the first embodiment, the magnet 283 is not moved with respect to the target plate 281 and the backing plate 282, and hence the magnet 283 may be fixed with respect to them. It should be noted that the magnet 283 may not be fixed to the backing plate 282, and the magnet 283 may be set to be movable by a driving source different from that for the backing plate 282.

The sputtering cathode Td is moved through a driving mechanism (not shown) with respect to the substrate 210 in a direction parallel to the surface to be sputtered of the target plate 281. The sputtering cathode Td takes a first position in which the target plate 281 is not opposed to the substrate 210, and a second position in which the target plate 281 is opposed to the substrate 210.

The sputtering by the vacuum processing apparatus configured in the above-mentioned manner will be described.

Similarly to the sputtering according to the first embodiment, due to the applied electrical field and magnetic field, the sputtering gas is converted into plasma. The region to be sputtered 280a on the target plate 281 is not moved on the target plate 281, and is fixed relative to the target plate 281. It should be noted that depending on the sputtering conditions such as the magnetic field intensity, the size and the shape of the region to be sputtered and the like can be changed.

At the start time of the sputtering, the sputtering cathode Td is located at a position in which the target plate 281 is not opposed to the substrate 210. Therefore, of the sputtered particles emitted from the region to be sputtered 280a of the target plate 281, only the sputtered particles emitted in the direction oblique to the surface to be sputtered arrive at the surface to be processed of the substrate 210, and the sputtered particles emitted in the perpendicular direction cannot arrive at the surface to be processed. While the target plate 281 is being sputtered, the sputtering cathode Td is moved.

In this manner, of the surface to be processed, a region in which the film is already formed of the sputtered particles incident in the oblique direction is subjected to further film formation using the sputtered particles incident in the perpendicular direction. On the other hand, a region in which no film has been formed is subjected to the film formation using the sputtered particles incident in the oblique direction. The sputtering cathode Td is moved continuously or intermittently, and the entire region of the surface to be processed of the substrate 210 is subjected to the film formation using the sputtered particles.

In the above-mentioned manner, it is possible to achieve film formation in which the damage received by the surface to be processed is small and the film-forming speed is kept high.

In the following, regarding the film formation using the sputtered particles emitted in the direction oblique to the surface to be sputtered of the target and the sputtered particles emitted in the direction perpendicular to the surface to be sputtered of the target, differences of the film-forming speed and the damage received by the base layer will be described.

FIG. 6 is a view of a schematic configuration of the sputtering apparatus, which describes an experiment that the inventors of the present invention were performed. This sputtering apparatus included two sputtering cathodes T1 and T2, each of which included a target 11, a backing plate 12, and a magnet 13. The backing plate 12 of each of the sputtering cathodes T1 and T2 was connected to each electrode of an alternating-current power source 14. For the target 11, a target material of In-Ga-Zn-O composition was used.

A substrate having a surface on which a silicon oxide film was formed as the gate insulating film was arranged to be opposed to the sputtering cathodes T1 and T2. The distance (TS distance) between the sputtering cathode and the substrate was set to 260 mm. The center of the substrate was set to correspond to a middle point (point A) between the sputtering cathodes T1 and T2. The distance from this point A to the center (point B) of each of the target 11 was 100 mm. Oxygen gas at a predetermined flow rate was introduced into a vacuum chamber kept in depressurized argon atmosphere (flow rate 230 sccm, partial pressure 0.74 Pa), and each of the target plates 11 was sputtered with plasma 15 generated by applying alternating-current power (0.6 kW) between the sputtering cathodes T1 and T2.

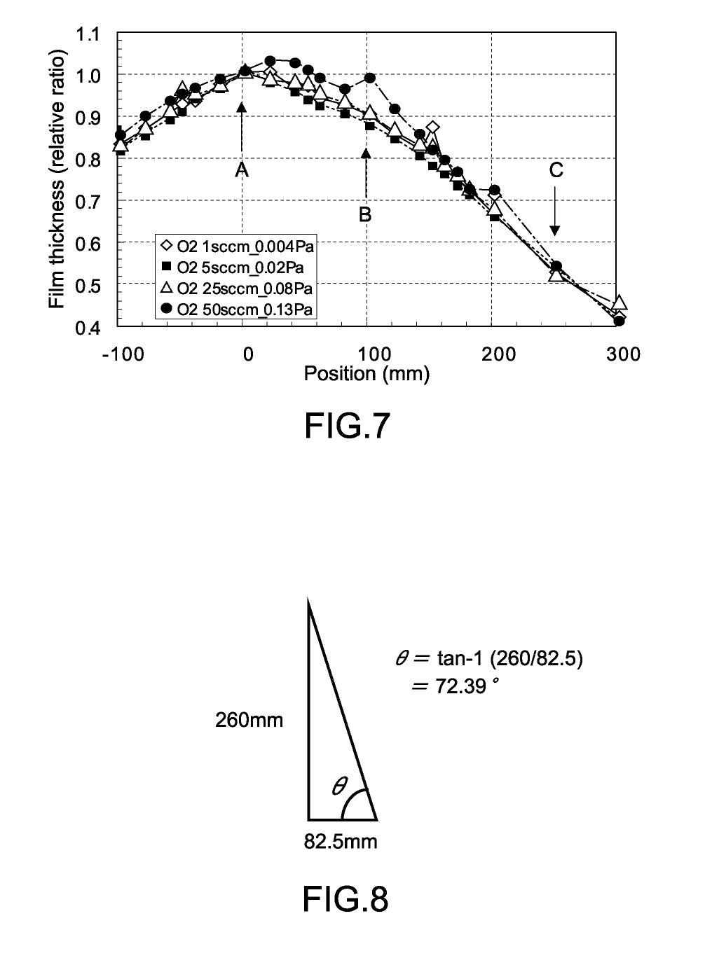

FIG. 7 shows measurement results of a film thickness at each position on the substrate, setting the point A as an original point. The film thickness at each point is represented as a relative ratio with respect to the film thickness of the point A set to 1. The temperature of the substrate was set to be equal to a room temperature. A point C indicates a position away from the point A by 250 mm. The distance from the outer periphery of the magnet 13 of the sputtering cathode T2 to the point C was 82.5 mm. In the drawing, a white diamond mark indicates a film thickness when the oxygen introduction amount was 1 sccm (partial pressure 0.004 Pa), a black square mark indicates a film thickness when the oxygen introduction amount was 5 sccm (partial pressure 0.02 Pa), a white triangle mark indicates a film thickness when the oxygen introduction amount was 25 sccm (partial pressure 0.08 Pa), and a black circle mark indicates a film thickness when the oxygen introduction amount was 50 sccm (partial pressure 0.14 Pa).

As shown in FIG. 7, the film thickness at the point A at which the sputtered particles emitted from the two sputtering cathodes T1 and T2 arrived was the largest. The film thickness was reduced while going away from the point A. The point C was a deposition region of the sputtered particles obliquely emitted from the sputtering cathode T2, and hence the film thickness at the point C was smaller than that at the deposition region (point B) of the sputtered particles perpendicularly emitted from the sputtering cathode T2. An incident angle e of the sputtered particles at this point C was 72.39° as shown in FIG. 8.

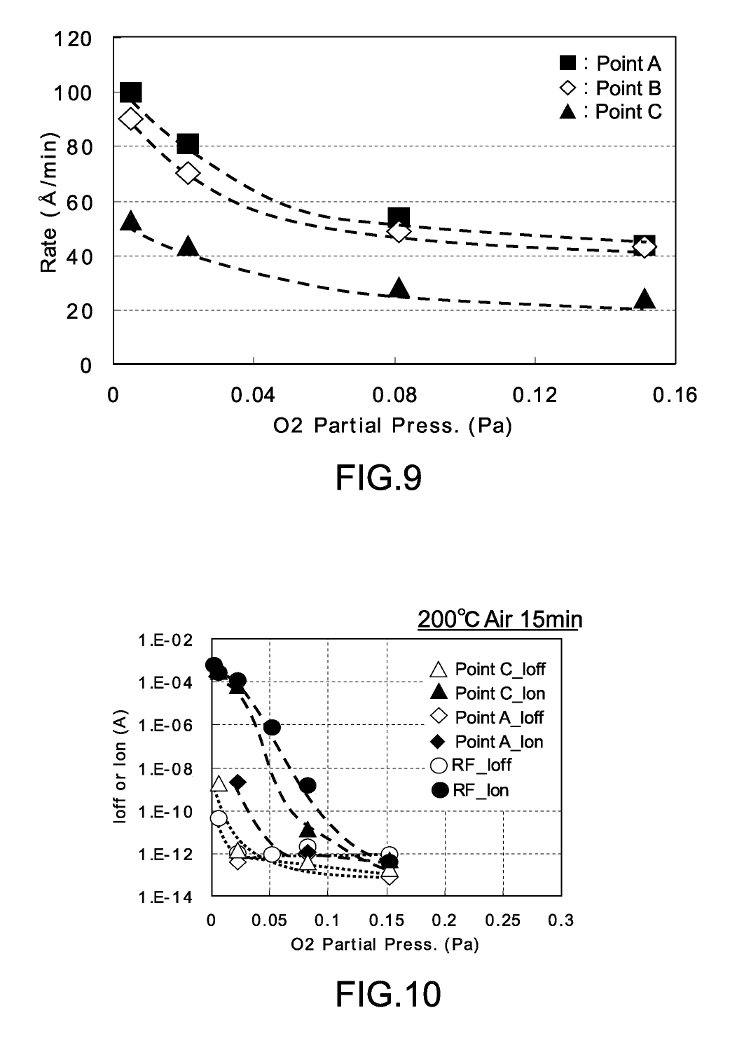

FIG. 9 is a view showing a relation between an introduced partial pressure and a film-forming rate, which was measured at each of the point A, the point B, and the point C. It was confirmed that irrespective of the film-forming position, as the oxygen partial pressure (oxygen introduction amount) becomes higher, the film-forming rate becomes lower.

At the point A and point C, thin-film transistors including the IGZO films, which were formed while varying the oxygen partial pressure, as the active layers were manufactured. By heating the sample of each transistor at 200° C. for 15 minutes in the atmosphere, the active layer was annealed. Then, with respect to each sample, ON-state current characteristics and OFF-state current characteristics were measured. The results are shown in FIG. 10. In the drawing, the vertical axis indicates ON-state current or OFF-state current, and the horizontal axis indicates an oxygen partial pressure during the formation of the IGZO film. As a reference, transistor properties of a sample including the IGZO film formed by an RF sputtering method using the passing-type film-forming method are shown together. In the drawing, a white triangle mark indicates an OFF-state current at the point C, a black triangle mark indicates an ON-state current at the point C, a white diamond mark indicates an OFF-state current at the point A, a black diamond mark indicates an ON-state current at the point A, a white circle mark indicates an OFF-state current of the reference sample, and a black circle mark indicates an ON-state current of the reference sample.

As will be clear from the results of FIG. 10, as the oxygen partial pressure becomes higher, the ON-state current decreases with respect to all of the samples. This is attributed to the fact that when oxygen concentration in the film becomes higher, the conductivity of the active layer becomes lower. Further, comparing the samples at the point A and the point C to each other, the sample at the point A has the ON-state current lower than that at the point C. This is attributed to the fact that during the formation of the active layer (IGZO film), a base film (gate insulating film) was greatly damaged due to collision of the sputtered particles, and hence the base film could not keep desired film quality. Further, the sample at the point C could obtain the ON-state current characteristics nearly equal to the ON-state current characteristics of the reference sample.

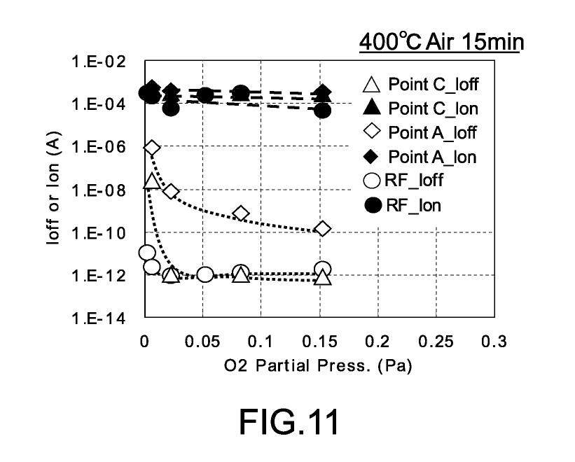

On the other hand, FIG. 11 shows results of an experiment in which the ON-state current characteristics and the OFF-state current characteristics of the thin-film transistor when the annealing condition of the active layer was set to be in the atmosphere, at 400° C., for 15 minutes were measured. Under this annealing condition, significant differences between the ON-state current characteristics of respective samples were not observed. However, it was confirmed that in regard to the OFF-state current characteristics, the sample at the point A is higher than each of the sample at the point C and the reference sample. This is attributed to the fact that during the formation of the active layer, the base film was greatly damaged due to collision of the sputtered particles, and hence the base film lost a desired insulating property.

Further, it was confirmed that by setting the annealing temperature to be high, it is possible to obtain high ON-state current characteristics without being affected by the oxygen partial pressure.

As will be clear from the above-mentioned results, in such a manner that when the active layer of the thin-film transistor is formed by sputtering, an initial layer of the thin-film is formed of the sputtered particles incident on the substrate in a direction oblique to the substrate, it is possible to obtain excellent transistor properties, that is, high ON-state current and low OFF-state current. Further, it is possible to stably manufacture the active layer of In-Ga-Zn-O-based composition, which has desired transistor properties.

Although the embodiments of the present invention have been described, it is needless to say that the present invention is not limited thereto and various modifications can be made based on the technical conception of the present invention.

Further, although in each of the above-mentioned embodiments, the description has been made by exemplifying the manufacturing method for the thin-film transistor including the IGZO film as the active layer, the present invention is also applicable in a case where a film made of another film-forming material such as a metal material is formed by sputtering.

Description of Reference numerals

10 substrate

11 target

13 magnet

61 first sputtering chamber

71 holding mechanism

80 target

83 magnet

93 supporting portion

100 vacuum processing apparatus

210 substrate

261 first sputtering chamber

280 target

283 magnet

1. A sputtering apparatus for forming a thin-film on a surface to be processed of a substrate, comprising:
a vacuum chamber capable of keeping a vacuum state;
a supporting portion, which is arranged in an inside of the vacuum chamber, and supports the substrate;
a target, which is arranged in parallel to the surface to be processed of the substrate supported by the supporting portion, and has a surface to be sputtered; and
a plasma generation means for generating plasma forming a region to be sputtered from which sputtered particles are emitted by sputtering the surface to be sputtered, and for moving the region to be sputtered between a first position in which the region to be sputtered is not opposed to the surface to be processed and a second position in which the region to be sputtered is opposed to the surface to be processed.

2. The sputtering apparatus according to claim 1, wherein
the plasma generation means includes a magnet for forming a magnetic field on a side of the surface to be sputtered of the target, and
the magnet is arranged to be movable relative to the supporting portion.

3. The sputtering apparatus according to claim 2, wherein the surface to be sputtered includes
a first region in which the surface to be sputtered is not opposed to the surface to be processed, and
a second region in which the surface to be sputtered is opposed to the surface to be processed; and
the magnet is arranged to be movable between the first region and the second region.

4. The sputtering apparatus according to claim 2, wherein the target moves together with the magnet.

5. A thin-film forming method, comprising:
arranging a substrate, which has a surface to be processed, in a vacuum chamber;
generating plasma for sputtering a target; and
moving a region to be sputtered of the target between a first position in which the region to be sputtered of the target is not opposed to the surface to be processed and a second position in which the region to be sputtered of the target is opposed to the surface to be processed.

6. A manufacturing method for a field effect transistor, comprising:
forming a gate insulating film on a substrate;
arranging the substrate in an inside of a vacuum chamber in which a target having In-Ga-Zn-O-based composition is arranged;
generating plasma for sputtering the target;
moving a region to be sputtered of the target between a first position in which the region to be sputtered of the target is not opposed to the surface to be processed and a second position in which the region to be sputtered of the target is opposed to the surface to be processed, to thereby form an active layer on the gate insulating film.
